(19) United States
(12) Patent Application Publication
(10) Pub. No.: US 2020/0066967 A1
(43) Pub. Date: Feb. 27, 2020

(54) DAMASCENE-BASED APPROACHES FOR FABRICATING A PEDESTAL FOR A MAGNETIC TUNNEL JUNCTION (MTJ) DEVICE AND THE RESULTING STRUCTURES

(71) Applicant: Intel Corporation, Santa Clara, CA (US)

(72) Inventors: Satyarth SURI, Portland, OR (US); Tejaswi K. INDUKURI, Boise, ID (US); Robert B. TURKOT, JR., Hillsboro, OR (US); James S. CLARKE, Portland, OR (US)

(21) Appl. No.: 16/068,078

(22) PCT Filed: Mar. 31, 2016
(86) PCT No.: PCT/US2016/025273

§ 371 Date: Jul. 3, 2018

(51) Int. Cl. H01L 43/02; G11C 11/16; H01L 43/12; H01L 27/22

(52) U.S. Cl. CPC H01L 43/02; H01L 27/222; H01L 43/12; G11C 11/161

(57) ABSTRACT

Damascene-based approaches for fabricating a pedestal for a magnetic tunnel junction (MTJ) device, and the resulting structures, are described. In an example, a magnetic tunnel junction (MTJ) device includes a metal line disposed in a dielectric layer disposed above a substrate, the metal line recessed below an uppermost surface of the dielectric layer. The MTJ device also includes a conductive pedestal disposed on the metal line and laterally adjacent to the dielectric layer. The MTJ device also includes a magnetic tunnel junction (MTJ) stack disposed on the conductive pedestal.

### TECHNICAL FIELD

Embodiments of the invention are in the field of integrated circuit fabrication and, in particular, damascene-based approaches for fabricating a pedestal for a magnetic tunnel junction (MTJ) device, and the resulting structures.

### BACKGROUND

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory devices on a chip, lending to the fabrication of products with increased capacity. The drive for ever-more capacity, however, is not without issue. The necessity to optimize the performance of each device becomes increasingly significant.

Non-volatile embedded memory, e.g., on-chip embedded memory with non-volatility can enable energy and computational efficiency. However, there may be density limitations for traditional spin torque transfer magnetoresistive random access memory (STT-MRAM) integration to accommodate large write switching current and select transistor requirements. Specifically, traditional STT-MRAM has a cell size limitation due to the drive transistor requirement to provide sufficient spin current. Furthermore, such memory is associated with large write current (>100 μA) and voltage (>0.7 V) requirements of conventional magnetic tunnel junction (MTJ) based devices.

As such, significant improvements are still needed in the area of non-volatile memory arrays based on MTJs.

### BRIEF DESCRIPTION OF THE DRAWINGS

FIGS. 1A and 1B illustrate cross-sectional views of process operations in the fabrication a magnetic tunnel junction (MTJ) device, in accordance with the prior art.

FIG. 2 illustrates a cross-sectional view of a plurality of MTJ devices, in accordance with an embodiment of the present invention.

FIGS. 3A-3D illustrate cross-sectional views representing various processing operations in a method of fabricating a magnetic tunnel junction (MTJ) device, in accordance with an embodiment of the present invention, wherein:

FIG. 3A illustrates a starting structure in the method of fabricating an MTJ device, including full metal lines disposed in an ILD layer disposed above a substrate;

FIG. 3B illustrates the structure of FIG. 3A following recessing of the full metal lines to provide recessed metal lines;

FIG. 3C illustrates the structure of FIG. 3B following formation of a pedestal material layer with overburden;

FIG. 3D illustrates the structure of FIG. 3C following a planarization process.

FIGS. 4A-4D illustrate cross-sectional views representing various processing operations in another method of fabricating a magnetic tunnel junction (MTJ) device, in accordance with another embodiment of the present invention, wherein:

FIG. 4A illustrates a starting structure in the method of fabricating an MTJ device, including full metal lines disposed in an ILD layer disposed above a substrate;

FIG. 4B illustrates the structure of FIG. 4A following recessing of the full metal lines to provide recessed metal lines;

FIG. 4C illustrates the structure of FIG. 4B following selective growth of a pedestal material layer;

FIG. 4D illustrates the structure of FIG. 4C following a planarization process.

FIGS. 5A and 5B illustrate cross-sectional views representing additional processing operations in a method of fabricating a magnetic tunnel junction (MTJ) device, in accordance with an embodiment of the present invention.

FIG. 6 illustrates a block diagram of an electronic system, in accordance with an embodiment of the present invention.

FIG. 7 illustrates a computing device in accordance with one embodiment of the invention.

FIG. 8 illustrates an interposer that includes one or more embodiments of the invention.

### DESCRIPTION OF THE EMBODIMENTS

Damascene-based approaches for fabricating a pedestal for a magnetic tunnel junction (MTJ) device, and the resulting structures, are described. In the following description, numerous specific details are set forth, such as specific magnetic tunnel junction (MTJ) layer regimes, in order to provide a thorough understanding of embodiments of the present invention. It will be apparent to one skilled in the art that embodiments of the present invention may be practiced without these specific details. In other instances, well-known features, such as operations associated with embedded memory, are not described in detail in order to not unnecessarily obscure embodiments of the present invention. Furthermore, it is to be understood that the various embodiments shown in the Figures are illustrative representations and are not necessarily drawn to scale.

One or embodiments of the present invention are directed to methods for creating an etch-free pedestal MTJ device (also referred to as a pedestal free MTJ device). Embodiments may pertain to one or more of magnetic tunnel junctions (MTJs), magnetic random access memory (MRAM), or spin transfer torque magnetoresistive random access memory (STT-MRAM).

To provide context, typical MRAM array stacks have an underlying metal layer, such as a metal line or via of a back end of line (BEOL) metallization layer. A pedestal layer is then deposited followed by MTJ layers. Reactive ion etch (RIE) chemistries used to etch such pedestal layer may cause damage to the MTJ devices and may require additional compatibility with the underlying metal layer. These constraints can be extremely challenging in the manufacturing of devices including such layers.

In accordance with one or more embodiments described herein, a metal feature such as a metal line of a metallization layer is recessed after initial formation. A conductive pedestal layer is then deposited and polished back to a flat front or uppermost surface. The need for a pedestal etch process is thus eliminated. Processing schemes described herein may further eliminate, or at least mitigate, the need for complex integration used to protect the sidewall of the MTJ layers and/or the development of new and expensive etch chemistries. In certain embodiments, the resulting pedestal layer is smooth or flat within the surrounding inter-layer dielectric (ILD), whereas previous solutions have resulted in a pedestal metal that is higher than the surrounding ILD.

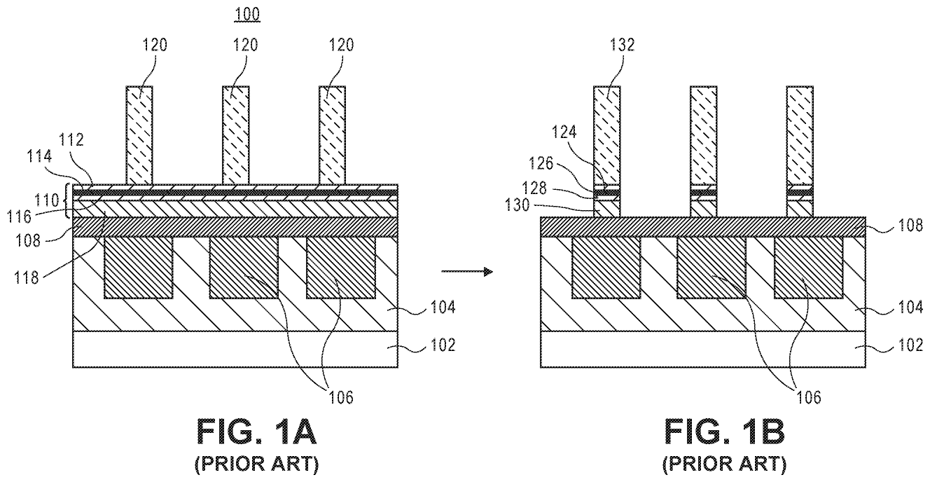

To provide further context, FIGS. 1A and 1B illustrate cross-sectional views of process operations in the fabrication a magnetic tunnel junction (MTJ) device, in accordance with the prior art.

Referring to FIG. 1A, a material stack 100 includes a substrate 102 having an interlayer dielectric (ILD) layer 104 thereon. Metal lines 106 are formed in the ILD layer. A continuous pedestal layer 108 is disposed above the ILD layer 104 and metal lines 106. An MTJ layer stack 110 including a free layer 112, a tunneling layer 114, a fixed layer 116, and a synthetic antiferromagnet (SAF) layer 118 is formed on the continuous pedestal layer 108. A conductive hardmask 120 is formed and patterned on the MTJ layer stack 110.

Referring to FIG. 1B, the MTJ layer stack 110 is etched to form discrete MTJ stacks with patterned free layer 124, patterned tunneling layer 126, patterned fixed layer 128, and patterned SAF layer 130. Also, hardmask layer 120 can ultimately serve as a top electrode 132. The etch of the MTJ layer stack 110 stops on the continuous pedestal layer 108. However, the continuous pedestal layer 108 ultimately needs to be etched to isolate discrete memory elements, also referred to as dots. The continuous pedestal layer 108 options can include but is not limited to ruthenium (Ru), tantalum (Ta), or titanium nitride (TiN), for example. The etch of such a layer may be difficult, especially considering that the needs to be selective to metal in trench line and the low k ILD should not be damaged. Furthermore, the sidewalls of patterned MTJ dots need to endure minimal damage, and the etch must be selective to hardmask/top electrode material. Other considerations includes that Ta or TiN layers typically require a halogen based etch, leads to device damage, and poor hardmask selectivity. On the other hand, Ru layers typically require an etch process involving oxygen, which can lead to copper (Cu) damage and ILD damage.

Addressing one or more of the above described issues, in accordance with one or more embodiments described herein, pedestal free processing is described, in that no etch patterning of the pedestal material is needed. In a generic embodiment, a process for fabricating a pedestal layer includes recessing a metal feature in a metallization layer, filling the recessed regions with a pedestal material, and polishing back to form a cladded metal line with pedestal material on top. Although a chemical mechanical planarization (CMP) process may be implemented to planarize the pedestal material to an underlying ILD layer, an etch of a continuous pedestal material is not required.

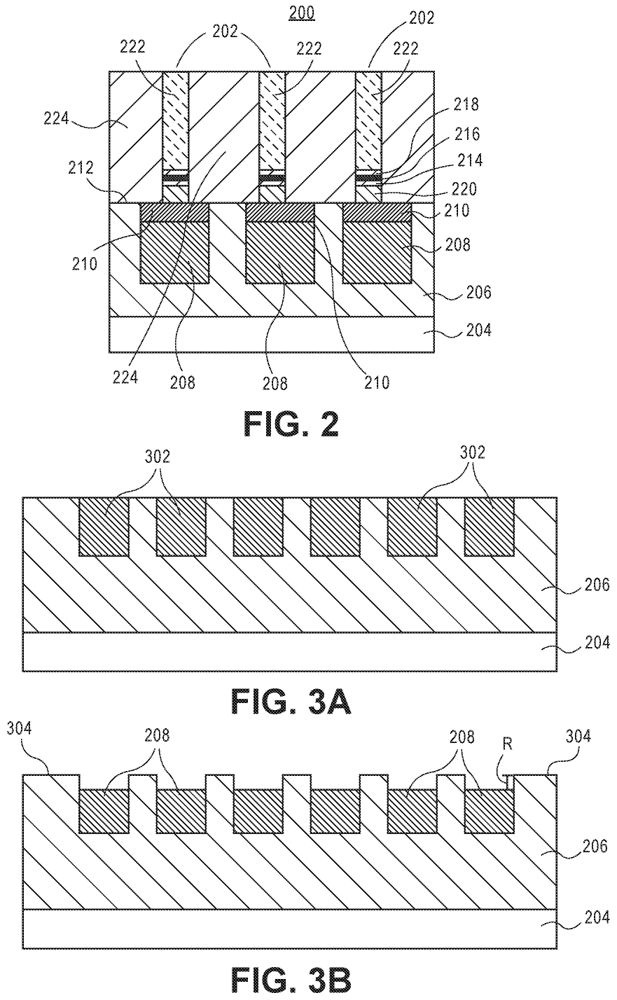

As an exemplary structure achieved upon implementing one or more approaches described herein, FIG. 2 illustrates a cross-sectional view of a plurality of MTJ devices, in accordance with an embodiment of the present invention.

Referring to FIG. 2, a semiconductor structure 200 includes a plurality of MTJ devices 202 disposed above a substrate 204. An ILD layer 206 is disposed above the substrate 204. Metal lines 208 are disposed in the ILD layer 206. A conductive pedestal layer 210 (also referred to as a lower electrode) is disposed on the metal lines 208 and within the ILD layer 206. In one embodiment, the conductive pedestal layer 210 is co-planar with an uppermost surface 212 of the ILD layer 206, as is depicted in FIG. 2.

Referring again to FIG. 2, each of the MTJ devices 202 includes a fixed layer 214, a tunneling layer 216, and a free layer 218. Optionally, in an embodiment, a SAF layer 220 is included proximate to the fixed layer 214, as is depicted in FIG. 2. Each MTJ device 202 also includes a hardmask/upper electrode 222 housed in an upper ILD layer 224. It is to be appreciated that the free and fixed layers may be reversed. However, if a lower SAF layer is included, the lower magnetic layer is typically a fixed layer while the upper layer serves as the free layer. It is also to be appreciated that interconnect layer(s) may be formed on top of the MTJ devices 202 of FIG. 2, e.g., using standard dual damascene process techniques that are well-known in the art.

It is also to be appreciated that although the MTJ devices 202 may actually include multiple layers of very thin metal films, for the sake of simplicity the MTJ film stack is divided into 4 portions in FIG. 2: bottom SAF and fixed magnetic MTJ films, tunnel barrier material, top free magnet MTJ films, and a MTJ top electrode layer. In an embodiment, the MTJ devices 202 are housed in a dielectric layer dedicated to memory devices. However, in other embodiments, the MTJ devices 202 are housed in a dielectric layer that is shared with a laterally adjacent metallization layer of a logic region of a chip. For example, in one embodiment, the MTJ devices 202 are embedded into a corresponding logic interconnect layer (e.g., M1, M2, M3, M4, etc.)

Using FIG. 2 as a backdrop, structural embodiments may generally include a magnetic tunnel junction (MTJ) device 202. A metal line 208 is disposed in a dielectric layer 206 disposed above a substrate 204. The metal line 208 is recessed below an uppermost surface 212 of the dielectric layer 206. The MTJ device 202 also includes a conductive pedestal 210 disposed on the metal line 208 and laterally adjacent to the dielectric layer 206. The MTJ device 202 also includes a magnetic tunnel junction (MTJ) stack (e.g., 214, 216 and 218 and, optionally 220) disposed on the conductive pedestal 210. In one embodiment, an uppermost surface of the conductive pedestal 210 is co-planar with an uppermost surface 212 of the dielectric layer 206, as is depicted in FIG. 2. In one embodiment, a portion of the conductive pedestal 210 is not covered by the MTJ stack, as is also depicted in FIG. 2. In one embodiment, the MTJ device 202 further includes a second dielectric layer 224 disposed on the dielectric layer 206 and laterally adjacent to the MTJ stack, as is also depicted in FIG. 2. In a specific such embodiment, a portion of the second dielectric layer 224 is disposed on a portion of the conductive pedestal 210, as is also depicted in FIG. 2. In one embodiment, the MTJ device 202 further includes an upper electrode 222 disposed on the MTJ stack. The upper electrode 222 has, from a top-down perspective, substantially the same shape as the MTJ stack, as is also depicted in FIG. 2. In one embodiment, the MTJ device further includes a second MTJ stack (e.g., three lines total shown) disposed on the conductive pedestal 210.

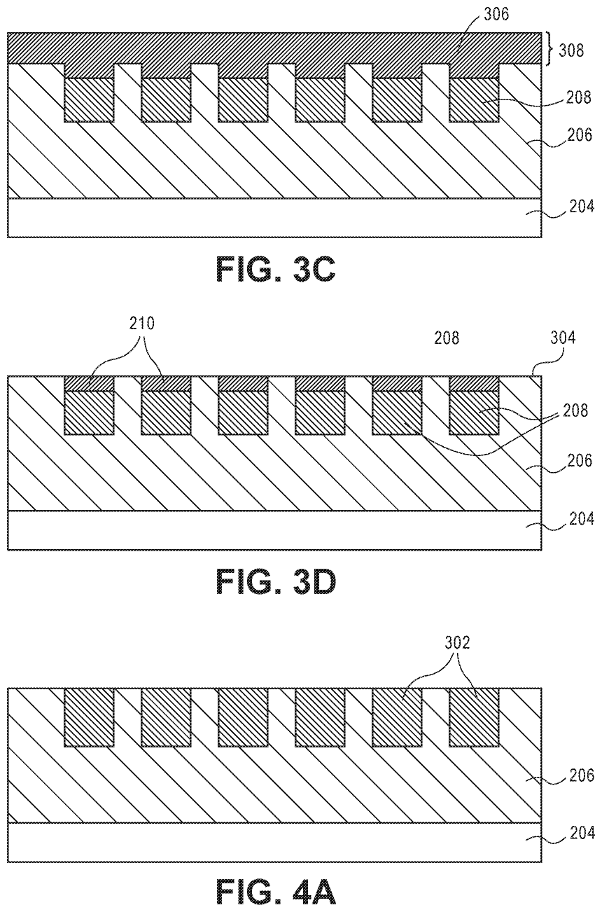

In a first exemplary processing scheme, FIGS. 3A-3D illustrate cross-sectional views representing various processing operations in a method of fabricating a magnetic tunnel junction (MTJ) device, in accordance with an embodiment of the present invention.

Referring to FIG. 3A, the fabrication approach begins with a starting structure at a stage that is post metallization layer CMP. In particular, an ILD layer 206 is disposed on a substrate 204. Full metal lines 302 are disposed in the ILD layer 206.

Referring to FIG. 3B, a controlled metal recess of the full metal lines 302 is performed on the structure of FIG. 3A to form recessed metal lines 208. The recessed metal lines 208 are recessed by amount R from the uppermost surface 304 of ILD layer 206. In an embodiment, the full metal lines 302 are recessed to form recessed metal lines using a dry etch process. In another embodiment, the full metal lines 302 are recessed to form recessed metal lines using a wet etch process. It is to be appreciated that the full metal lines may include a liner metal layer and a fill layer. In an embodiment, the liner metal layer and the fill metal layer are recessed to approximately the same extent. Other embodiments, however, may include recessing of the liner metal layer to a lesser or greater extent relative to the fill metal layer.

Referring to FIG. 3C, a pedestal material layer 306 is formed on the structure of FIG. 3B. The pedestal material layer 306 is formed on the recessed metal lines 208 and includes an overburden portion 308 formed above the ILD layer 206. The pedestal material layer may be formed by a process such as, but not limited to, a chemical or atomic layer deposition process, a physical vapor deposition process, or an electroplating process.

Referring to FIG. 3D, the pedestal material layer 306 of the structure of FIG. 3C is subjected to a chemical mechanical planarization (CMP) process. The CMP process a conductive pedestal/lower electrode layer 210. In one embodiment, the pedestal layer 210 is co-planar with the uppermost surface 304 of the ILD layer 206, as is depicted in FIG. 3D. Thus, in a specific embodiment, a self-aligned pedestal is achieved. The conductive pedestal 210 is confined within and laterally adjacent to the dielectric layer 206.

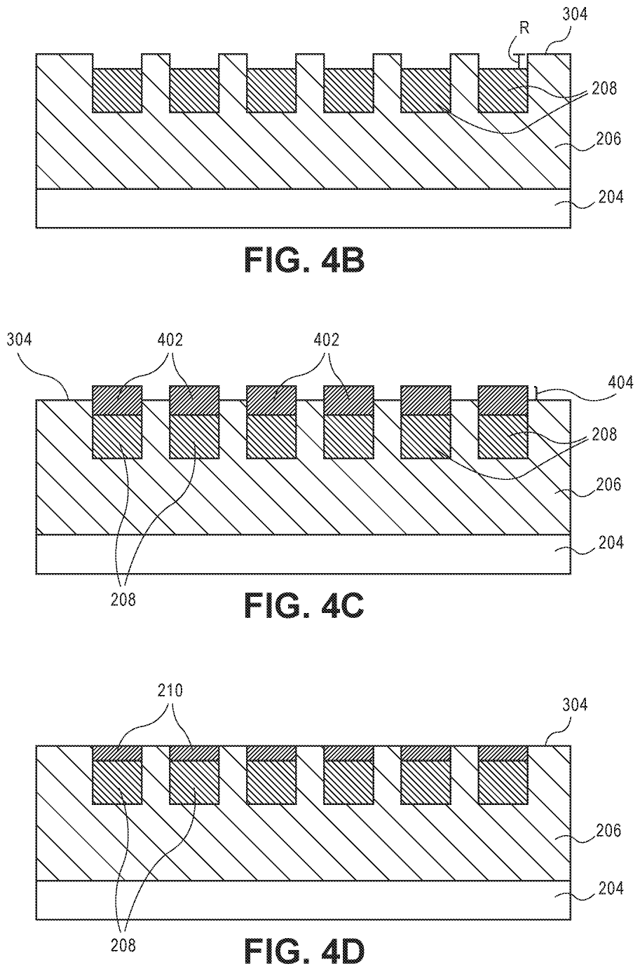

In a second exemplary processing scheme, FIGS. 4A-4D illustrate cross-sectional views representing various processing operations in a method of fabricating a magnetic tunnel junction (MTJ) device, in accordance with an embodiment of the present invention.

Referring to FIG. 4A, the fabrication approach begins with a starting structure at a stage that is post metallization layer CMP. In particular, an ILD layer 206 is disposed on a substrate 204. Full metal lines 302 are disposed in the ILD layer 206.

Referring to FIG. 4B, a controlled metal recess of the full metal lines 302 is performed on the structure of FIG. 4A to form recessed metal lines 208. The recessed metal lines 208 are recessed by amount R from the uppermost surface 304 of ILD layer 206. In an embodiment, the full metal lines 302 are recessed to form recessed metal lines using a dry etch process. In another embodiment, the full metal lines 302 are recessed to form recessed metal lines using a wet etch process. It is to be appreciated that the full metal lines may include a liner metal layer and a fill layer. In an embodiment, the liner metal layer and the fill metal layer are recessed to approximately the same extent. Other embodiments, however, may include recessing of the liner metal layer to a lesser or greater extent relative to the fill metal layer.

Referring to FIG. 4C, a pedestal material layer 402 is selectively grown on the recessed metal lines 208 of the structure of FIG. 4B. The pedestal material layer 402 is formed on the recessed metal lines 208. Overburden portions are not formed since the growth is selective. However, the lines may be formed to an excess 404 having a height above the upper surface 304 of the ILD layer 206 and includes an overburden portion 404 formed above the ILD layer 206. In a particular embodiment, although a full overburden may not form (such as shown in FIG. 3C), such selective growth can have a lateral mushroom when it reaches above the ILD surface 304. The pedestal material layer may be formed by a process such as, but not limited to, a chemical or atomic layer deposition process or an electroplating process.

Referring to FIG. 4D, the pedestal material layer 402 of the structure of FIG. 4C is subjected to a chemical mechanical planarization (CMP) process. The CMP process results in a conductive pedestal/lower electrode layer 210. In one embodiment, the pedestal layer 210 is co-planar with the uppermost surface 304 of the ILD layer 206, as is depicted in FIG. 4D. Thus, in a specific embodiment, a self-aligned pedestal is achieved. The conductive pedestal 210 is confined within and laterally adjacent to the dielectric layer 206.

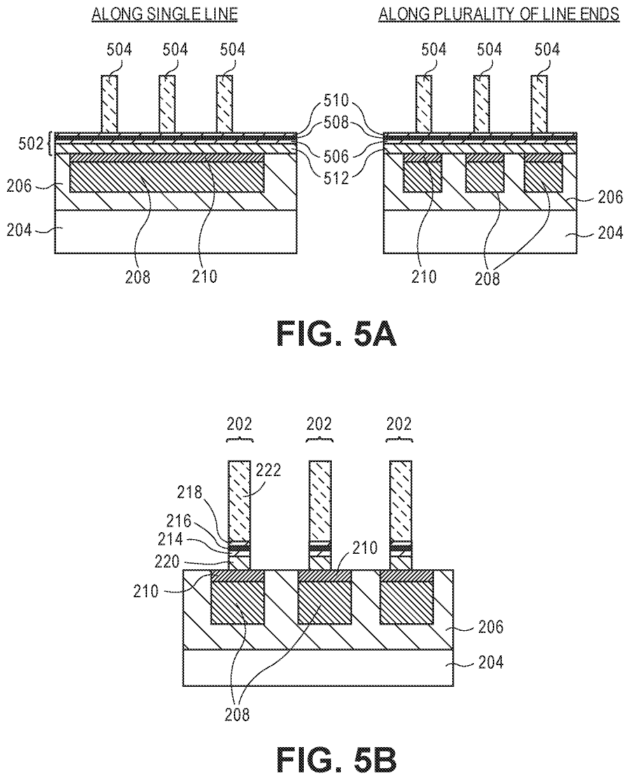

FIGS. 5A and 5B illustrate cross-sectional views representing additional processing operations in a method of fabricating a magnetic tunnel junction (MTJ) device, in accordance with an embodiment of the present invention.

Referring to FIG. 5A, the structure of FIG. 3D or 4D has an MTJ material stack 502 formed thereon. Cross-sectional views are shown both (i) taken along a single line and (ii) along a plurality of line ends. A conductive hardmask 504 is formed and patterned above the MTJ material stack 502. The MTJ material stack 502 includes a fixed layer 506, a tunneling layer 508, a free layer 510, and an optional SAF layer 512.

Referring to FIG. 5B, the MTJ material stack 502 is etched to provide discrete MTJ devices 202. The MTJ stack may be patterned using the conductive hardmask 504 as an etch mask. The conductive hardmask 504 may ultimately become an upper electrode 222 (or at least a portion of an upper electrode) of an MTJ device. The structure of FIG. 5B includes substrate 204, ILD layer 206, metal lines 208, and pedestal/lower electrode 210 disposed within ILD layer 206 and co-planar with an uppermost surface of the ILD layer 206. Each MTJ device includes a fixed layer 214, a tunneling layer 216, and a free layer 218, and, optionally, an SAF layer 220 proximate the fixed layer 214, as is depicted in FIG. 5B.

Referring again now to FIG. 2, further processing of the structure of FIG. 5B may include formation of a second ILD layer 224. As described in association with FIG. 2, interconnect layer(s) may be formed on top of the MTJ devices of FIG. 2, e.g., using standard dual damascene process trench and via patterning, barrier/seed dep, copper electroplate, and CMP processes, as are well-known in the art.

Referring again to FIGS. 2, 3A-3D, 4A-4D, 5A and 5B, in an embodiment, the free layer MTJ film or films 218 (or, alternatively, 214) is composed of a material suitable for transitioning between a majority spin and a minority spin, depending on the application. Thus, the free magnetic layer (or memory layer) may be referred to as a ferromagnetic memory layer. In one embodiment, the free magnetic layer is composed of a layer of cobalt iron (CoFe) or cobalt iron boron (CoFeB).

Referring again to FIGS. 2, 3A-3D, 4A-4D, 5A and 5B, in an embodiment, the dielectric or tunneling layer 216 is composed of a material suitable for allowing current of a majority spin to pass through the layer, while impeding at least to some extent current of a minority spin to pass through the layer. Thus, the dielectric or tunneling layer 216 (or spin filter layer) may be referred to as a tunneling layer. In one embodiment, the dielectric layer is composed of a material such as, but not limited to, magnesium oxide (MgO) or aluminum oxide (Al₂O₃). In one embodiment, the dielectric layer has a thickness of approximately 1 nanometer.

Referring again to FIGS. 2, 3A-3D, 4A-4D, 5A and 5B, in an embodiment, the fixed layer MTJ film or films 214 (or 218 in the case that 214 is a free layer) is composed of a material or stack of materials suitable for maintaining a fixed majority spin. Thus, the fixed magnetic layer (or reference layer) may be referred to as a ferromagnetic layer. In one embodiment, the fixed magnetic layer is composed of a single layer of cobalt iron boron (CoFeB). However, in another embodiment, the fixed magnetic layer is composed of a cobalt iron boron (CoFeB) layer, ruthenium (Ru) layer, cobalt iron boron (CoFeB) layer stack. In an embodiment, as depicted, a synthetic antiferromagnet (SAF) layer 220 is disposed directly beneath the fixed layer MTJ film or films 214.

Referring again to FIGS. 2, 3A-3D, 4A-4D, 5A and 5B, in an embodiment, the plurality of conductive pedestals 210 includes a thick metal nitride layer, such as a relatively thick titanium nitride (TiN) layer or tantalum nitride (TaN) layer. In another embodiment, the conductive metal layer 210 is an essentially pure metal layer such as a layer of ruthenium (Ru) or tantalum (Ta). In one embodiment, the conductive metal layer 210 is referred to as a “thin via” layer or a bottom electrode layer.

Referring again to FIGS. 2, 3A-3D, 4A-4D, 5A and 5B, in an embodiment, the conductive hardmask or top electrode 222 is composed of a material or stack of materials suitable for electrically contacting the free layer MTJ film or films 218 (or, alternatively, the fixed film). In an embodiment, the top electrode 222 is a topographically smooth electrode. In one such embodiment, the top electrode 222 has a thickness suitable for good conductivity but has little to no columnar structure formation that would otherwise lead to a rough top surface. Such a topographically smooth electrode may be referred to as amorphous in structure. In a specific embodiment, the top electrode 222 is composed of Ru layers interleaved with Ta layers, with a thicker layer of titanium nitride disposed thereon. Effectively, in accordance with an embodiment of the present invention, the top electrode 222 may not be a conventional thick single metal electrode, such as a Ru electrode, but is instead a Ru/Ta interleaved materials stack. In alternative embodiments, however, the top electrode 222 is a conventional thick single metal electrode, such as a Ta or Ru electrode.

Referring again to FIGS. 2, 3A-3D, 4A-4D, 5A and 5B, in an embodiment, one or more interlayer dielectrics (ILD), such as inter-layer dielectric material layers 206 and 224, are used. The ILD layers may be formed using dielectric materials known for their applicability in integrated circuit structures, such as low-k dielectric materials. Examples of dielectric materials that may be used include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layers may include pores or air gaps to further reduce their dielectric constant.

Referring again to FIGS. 2, 3A-3D, 4A-4D, 5A and 5B, in an embodiment, the metal lines 208 are composed of one or more metal or other conductive structures. A common example is the use of copper lines and structures that may or may not include barrier layers between the copper and surrounding ILD material. As used herein, the term metal includes alloys, stacks, and other combinations of multiple metals. For example, the metal interconnect lines may include barrier layers, stacks of different metals or alloys, etc. The interconnect lines are also sometimes referred to in the arts as traces, wires, lines, metal, or simply interconnect.

Referring again to FIGS. 2, 3A-3D, 4A-4D, 5A and 5B, in an embodiment, substrate 204 is a semiconductor substrate. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. Although a few examples of materials from which the substrate may be formed are described here, any material that may serve as a foundation upon which a semiconductor device may be built falls within the spirit and scope of the present invention.

It is to be appreciated that the layers and materials described in association with FIGS. 2, 3A-3D, 4A-4D, 5A and 5B are typically formed on or above an underlying semiconductor substrate or structure, such as underlying device layer(s) of an integrated circuit. In an embodiment, an underlying semiconductor substrate 204 represents a general workpiece object used to manufacture integrated circuits. The semiconductor substrate often includes a wafer or other piece of silicon or another semiconductor material. Suitable semiconductor substrates include, but are not limited to, single crystal silicon, polycrystalline silicon and silicon on insulator (SOD, as well as similar substrates formed of other semiconductor materials. The semiconductor substrate, depending on the stage of manufacture, often includes transistors, integrated circuitry, and the like. The substrate may also include semiconductor materials, metals, dielectrics, dopants, and other materials commonly found in semiconductor substrates. In one embodiment, the illustrated structures depicted in FIGS. 2, 3A-3D, 4A-4D, 5A and 5B are fabricated on underlying transistor or other semiconductor device layer(s) formed in or above the substrate 204. In another embodiment, the illustrated structures depicted in FIGS. 2, 3A-3D, 4A-4D, 5A and 5B are fabricated on underlying lower level interconnect layers formed above the substrate 204.

Although the above damascene-based approaches for fabricating a pedestal for a magnetic tunnel junction (MTJ) device have been described in detail with respect to select operations, it is to be appreciated that additional or intermediate operations for fabrication may include standard microelectronic fabrication processes such as lithography, etch, thin films deposition, planarization (such as chemical mechanical polishing (CMP)), diffusion, metrology, the use of sacrificial layers, the use of etch stop layers, the use of planarization stop layers, and/or any other associated action with microelectronic component fabrication.

It is also to be appreciated that in certain aspects and at least some embodiments of the present invention, certain terms hold certain definable meanings. For example, a “free” magnetic layer is a magnetic layer storing a computational variable. A “fixed” magnetic layer is a magnetic layer with fixed magnetization (magnetically harder than the free magnetic layer). A tunneling barrier, such as a tunneling dielectric or tunneling oxide, is one located between free and fixed magnetic layers. A fixed magnetic layer may be patterned to create inputs and outputs to an associated circuit. Magnetization may be written by spin hall effect. Magnetization may be read via the tunneling magneto-resistance effect while applying a voltage. In an embodiment, the role of the dielectric layer is to cause a large magneto-resistance ratio. The magneto-resistance is the ratio of the difference between resistances when the two ferromagnetic layers have anti-parallel magnetizations and the resistance of the state with the parallel magnetizations over the resistance of the state with parallel magnetizations.

In an embodiment, the MTJ functions essentially as a resistor, where the resistance of an electrical path through the MTJ may exist in two resistive states, either “high” or “low,” depending on the direction or orientation of magnetization in the free magnetic layer and in the fixed magnetic layer. In the case that the spin direction is of minority in the free magnetic layer, a high resistive state exists, wherein direction of magnetization in the free magnetic layer and the fixed magnetic layer are substantially opposed or anti-parallel with one another. In the case that the spin direction is of majority in the free magnetic layer, a low resistive state exists, wherein the direction of magnetization in the free magnetic layer and the fixed magnetic layer is substantially aligned or parallel with one another. It is to be understood that the terms “low” and “high” with regard to the resistive state of the MTJ are relative to one another. In other words, the high resistive state is merely a detectibly higher resistance than the low resistive state, and vice versa. Thus, with a detectible difference in resistance, the low and high resistive states can represent different bits of information (i.e. a “0” or a “1”).

Thus, the MTJ may store a single bit of information (“0” or “1”) by its state of magnetization. The information stored in the MTJ is sensed by driving a current through the MTJ. The free magnetic layer does not require power to retain its magnetic orientations. As such, the state of the MTJ is preserved when power to the device is removed. Therefore, a memory bit cell such as depicted in FIG. 1 is, in an embodiment, non-volatile.

In accordance with an embodiment of the present invention, each bit of data is stored in a separate magnetic tunnel junction (MTJ). The MTJ is a magnetic element that includes two magnetic layers separated by a thin insulating tunnel barrier layer. One of the magnetic layers is referred to as the reference layer, the fixed layer, or the pinned magnetic layer, and it provides a stable reference magnetic orientation. The bit is stored in the second magnetic layer which is called the free layer, and the orientation of the magnetic moment of the free layer can be either in one of two states—parallel to the reference layer or anti-parallel to the reference layer. Because of the tunneling magneto-resistance (TMR) effect, the electrical resistance of the anti-parallel state is significantly higher compared to the parallel state. To write information in a STT-MRAM device, the spin transfer torque effect is used to switch the free layer from the parallel to anti-parallel state and vice versa. The passing of current through the MTJ produces spin polarized current, which results in a torque being applied to the magnetization of the free layer. When the spin polarized current is sufficiently strong, enough torque is applied to the free layer to cause its magnetic orientation to change, thus allowing for bits to be written. To read the stored bit, the sensing circuitry measures the resistance of the MTJ. Since the sensing circuitry needs to determine whether the MTJ is in the low resistance (e.g. parallel) state or in the high resistance state (e.g. anti-parallel) with acceptable signal-to-noise, the STT-MRAM cell needs to be designed such that the overall electrical resistance and resistance variation of the cell are minimized.

Relating to one or more embodiments described herein, it is to be appreciated that traditional DRAM memory is facing severe scaling issues and, so, other types of memory devices are being actively explored in the electronics industry. One future contender is STT-MRAM devices. Embodiments described herein include a fabrication method for embedding STT-MRAM bit cell arrays into a logic process technology. Embodiments described may be advantageous for processing schemes involving the fabrication of logic processors with embedded memory arrays.

In an embodiment, transistors associated with substrate 204 are metal-oxide-semiconductor field-effect transistors (MOSFET or simply MOS transistors), fabricated on the substrate 204. In various implementations of the invention, the MOS transistors may be planar transistors, nonplanar transistors, or a combination of both. Nonplanar transistors include FinFET transistors such as double-gate transistors and tri-gate transistors, and wrap-around or all-around gate transistors such as nanoribbon and nanowire transistors.

In an embodiment, each MOS transistor of substrate 204 includes a gate stack formed of at least two layers, a gate dielectric layer and a gate electrode layer. The gate dielectric layer may include one layer or a stack of layers. The one or more layers may include silicon oxide, silicon dioxide (Sift) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The gate electrode layer of each MOS transistor of substrate 204 is formed on the gate dielectric layer and may consist of at least one P-type workfunction metal or N-type workfunction metal, depending on whether the transistor is to be a PMOS or an NMOS transistor. In some implementations, the gate electrode layer may consist of a stack of two or more metal layers, where one or more metal layers are workfunction metal layers and at least one metal layer is a fill metal layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a workfunction that is between about 3.9 eV and about 4.2 eV.

In some implementations, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further implementations of the invention, the gate electrode may consist of a combination of U-shaped structures and planar, non-U-shaped structures. For example, the gate electrode may consist of one or more U-shaped metal layers formed atop one or more planar, non-U-shaped layers.

In some implementations of the invention, a pair of sidewall spacers may be formed on opposing sides of the gate stack that bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In an alternate implementation, a plurality of spacer pairs may be used, for instance, two pairs, three pairs, or four pairs of sidewall spacers may be formed on opposing sides of the gate stack.

As is well known in the art, source and drain regions are formed within the substrate adjacent to the gate stack of each MOS transistor. The source and drain regions are generally formed using either an implantation/diffusion process or an etching/deposition process. In the former process, dopants such as boron, aluminum, antimony, phosphorous, or arsenic may be ion-implanted into the substrate to form the source and drain regions. An annealing process that activates the dopants and causes them to diffuse further into the substrate typically follows the ion implantation process. In the latter process, the substrate may first be etched to form recesses at the locations of the source and drain regions. An epitaxial deposition process may then be carried out to fill the recesses with material that is used to fabricate the source and drain regions. In some implementations, the source and drain regions may be fabricated using a silicon alloy such as silicon germanium or silicon carbide. In some implementations the epitaxially deposited silicon alloy may be doped in situ with dopants such as boron, arsenic, or phosphorous. In further embodiments, the source and drain regions may be formed using one or more alternate semiconductor materials such as germanium or a group III-V material or alloy. And in further embodiments, one or more layers of metal and/or metal alloys may be used to form the source and drain regions.

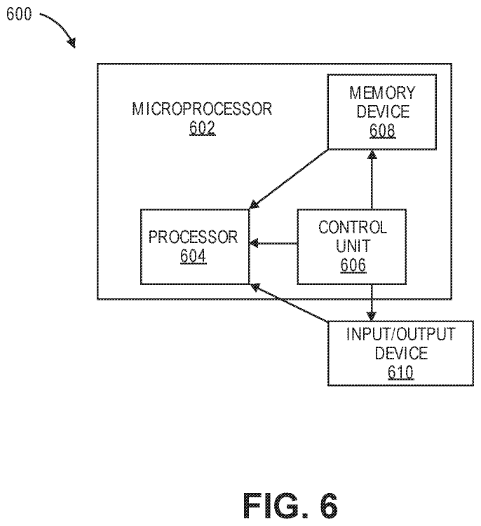

FIG. 6 illustrates a block diagram of an electronic system 600, in accordance with an embodiment of the present invention. The electronic system 600 can correspond to, for example, a portable system, a computer system, a process control system, or any other system that utilizes a processor and an associated memory. The electronic system 600 may include a microprocessor 602 (having a processor 604 and control unit 606), a memory device 608, and an input/output device 610 (it is to be understood that the electronic system 600 may have a plurality of processors, control units, memory device units and/or input/output devices in various embodiments). In one embodiment, the electronic system 600 has a set of instructions that define operations which are to be performed on data by the processor 604, as well as, other transactions between the processor 604, the memory device 608, and the input/output device 610. The control unit 606 coordinates the operations of the processor 604, the memory device 608 and the input/output device 610 by cycling through a set of operations that cause instructions to be retrieved from the memory device 608 and executed. The memory device 608 can include STT-MRAM memory arrays integrated into a logic processor, as described herein. In an embodiment, the memory device 608 is embedded in the microprocessor 602, as depicted in FIG. 6.

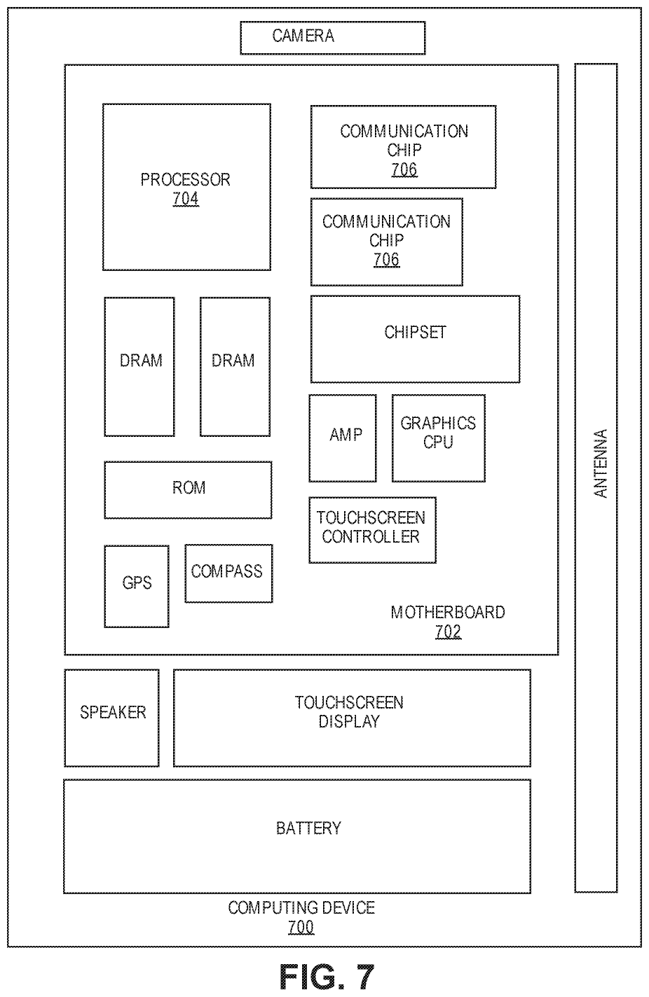

FIG. 7 illustrates a computing device 700 in accordance with one embodiment of the invention. The computing device 700 houses a board 702. The board 702 may include a number of components, including but not limited to a processor 704 and at least one communication chip 706. The processor 704 is physically and electrically coupled to the board 702. In some implementations the at least one communication chip 706 is also physically and electrically coupled to the board 702. In further implementations, the communication chip 706 is part of the processsor 704.

Depending on its applications, computing device 700 may include other components that may or may not be physically and electrically coupled to the board 702. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 706 enables wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 706 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 700 may include a plurality of communication chips 706. For instance, a first communication chip 706 may be dedicated to shorter range wireless communications such as Wi-Fi and Bluetooth and a second communication chip 706 may be dedicated to longer range wireless communications such as GPS, EDGE, GPRS, CDMA, WiMAX, LTE, Ev-DO, and others.

The processor 704 of the computing device 700 includes an integrated circuit die packaged within the processor 704. In some implementations of embodiments of the invention, the integrated circuit die of the processor includes one or more arrays, such as STT-MRAM memory arrays integrated into a logic processor, built in accordance with embodiments of the present invention. The term “processor” may refer to any device or portion of a device that processes electronic data from registers and/or memory to transform that electronic data into other electronic data that may be stored in registers and/or memory.

The communication chip 706 also includes an integrated circuit die packaged within the communication chip 706. In accordance with another implementation of an embodiment of the invention, the integrated circuit die of the communication chip includes STT-MRAM memory arrays integrated into a logic processor, built in accordance with embodiments of the present invention.

In further implementations, another component housed within the computing device 700 may contain a stand-alone integrated circuit memory die that includes one or more arrays, such as STT-MRAM memory arrays integrated into a logic processor, built in accordance with embodiments of the present invention.

In various implementations, the computing device 700 may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device 700 may be any other electronic device that processes data.

Accordingly, one or more embodiments of the present invention relate generally to the fabrication of embedded microelectronic memory. The microelectronic memory may be non-volatile, wherein the memory can retain stored information even when not powered. One or more embodiments of the present invention relate to the fabrication of STT-MRAM memory arrays integrated into a logic processor. Such arrays may be used in an embedded non-volatile memory, either for its non-volatility, or as a replacement for embedded dynamic random access memory (eDRAM). For example, such an array may be used for 1T-1X memory or 2T-1X memory (X=capacitor or resistor) at competitive cell sizes within a given technology node.

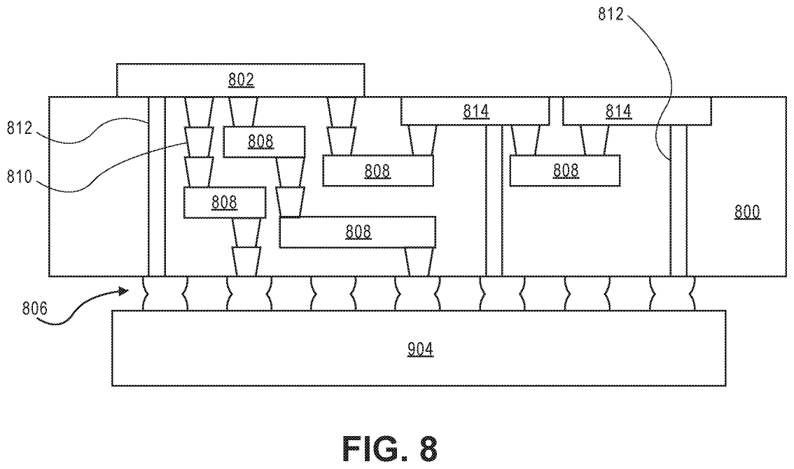

FIG. 8 illustrates an interposer 800 that includes one or more embodiments of the invention. The interposer 800 is an intervening substrate used to bridge a first substrate 802 to a second substrate 804. The first substrate 802 may be, for instance, an integrated circuit die. The second substrate 804 may be, for instance, a memory module, a computer motherboard, or another integrated circuit die. Generally, the purpose of an interposer 800 is to spread a connection to a wider pitch or to reroute a connection to a different connection. For example, an interposer 800 may couple an integrated circuit die to a ball grid array (BGA) 806 that can subsequently be coupled to the second substrate 804. In some embodiments, the first and second substrates 802/804 are attached to opposing sides of the interposer 800. In other embodiments, the first and second substrates 802/804 are attached to the same side of the interposer 800. And in further embodiments, three or more substrates are interconnected by way of the interposer 800.

The interposer 800 may be formed of an epoxy resin, a fiberglass-reinforced epoxy resin, a ceramic material, or a polymer material such as polyimide. In further implementations, the interposer may be formed of alternate rigid or flexible materials that may include the same materials described above for use in a semiconductor substrate, such as silicon, germanium, and other group III-V and group IV materials.

The interposer may include metal interconnects 808 and vias 810, including but not limited to through-silicon vias (TSVs) 812. The interposer 800 may further include embedded devices 814, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 800. In accordance with embodiments of the invention, apparatuses or processes disclosed herein may be used in the fabrication of interposer 800.

Thus, embodiments of the present invention include damascene-based approaches for fabricating a pedestal for a magnetic tunnel junction (MTJ) device, and the resulting structures.

In an embodiment, a magnetic tunnel junction (MTJ) device includes a metal line disposed in a dielectric layer disposed above a substrate, the metal line recessed below an uppermost surface of the dielectric layer. The MTJ device also includes a conductive pedestal disposed on the metal line and laterally adjacent to the dielectric layer. The MTJ device also includes a magnetic tunnel junction (MTJ) stack disposed on the conductive pedestal.

In one embodiment, an uppermost surface of the conductive pedestal is co-planar with the uppermost surface of the dielectric layer.

In one embodiment, a portion of the conductive pedestal is not covered by the MTJ stack.

In one embodiment, the MTJ device further includes a second dielectric layer disposed on the dielectric layer and laterally adjacent to the MTJ stack. A portion of the second dielectric layer is disposed on a portion of the conductive pedestal.

In one embodiment, the MTJ device further includes an upper electrode disposed on the MTJ stack. The upper electrode has, from a top-down perspective, substantially the same shape as the MTJ stack.

In one embodiment, the MTJ stack includes a fixed magnetic layer disposed above the conductive pedestal, a tunneling layer disposed on the fixed magnetic layer, and a free magnetic layer disposed on the tunneling layer.

In one embodiment, the MTJ stack further includes a synthetic antiferromagnet (SAF) layer disposed directly between the fixed magnetic layer and the conductive pedestal.

In one embodiment, the MTJ device further includes a second MTJ stack disposed on the conductive pedestal.

In an embodiment, a method of fabricating a magnetic tunnel junction (MTJ) device includes forming a metal line in a dielectric layer formed above a substrate, recessing the metal line below an uppermost surface of the dielectric layer, forming a conductive layer on the recessed metal line and over the uppermost surface of the dielectric layer, planarizing the conductive layer to form a conductive pedestal on the metal line, the conductive pedestal confined within and laterally adjacent to the dielectric layer, and forming a magnetic tunnel junction (MTJ) stack on the conductive pedestal.

In one embodiment, planarizing the conductive layer includes forming an uppermost surface of the conductive pedestal co-planar with the uppermost surface of the dielectric layer.

In one embodiment, forming the MTJ stack includes forming the MTJ stack on only a portion of the conductive pedestal.

In one embodiment, the method further includes forming a second dielectric layer on the dielectric layer and laterally adjacent to the MTJ stack, a portion of the second dielectric layer formed on a portion of the conductive pedestal.

In one embodiment, forming the MTJ stack includes forming a patterned conductive hardmask on a stack of MTJ layers, and etching the stack of MTJ layers using an etch process that terminates on the conductive pedestal.

In one embodiment, forming the MTJ stack includes forming a fixed magnetic layer above the conductive pedestal, forming a tunneling layer on the fixed magnetic layer, and forming a free magnetic layer on the tunneling layer.

In one embodiment, forming the MTJ stack further includes forming a synthetic antiferromagnet (SAF) layer on the conductive pedestal, and forming the fixed magnetic layer on the SAF layer.

In one embodiment, the method further includes forming a second MTJ stack on the conductive pedestal.

In an embodiment, a method of fabricating a magnetic tunnel junction (MTJ) device includes forming a metal line in a dielectric layer formed above a substrate, recessing the metal line below an uppermost surface of the dielectric layer, selectively forming a conductive layer on the recessed metal line to a height above the uppermost surface of the dielectric layer, planarizing the conductive layer to form a conductive pedestal on the metal line, the conductive pedestal confined within and laterally adjacent to the dielectric layer, and forming a magnetic tunnel junction (MTJ) stack on the conductive pedestal.

In one embodiment, planarizing the conductive layer includes forming an uppermost surface of the conductive pedestal co-planar with the uppermost surface of the dielectric layer.

In one embodiment, forming the MTJ stack includes forming the MTJ stack on only a portion of the conductive pedestal.

In one embodiment, the method further includes forming a second dielectric layer on the dielectric layer and laterally adjacent to the MTJ stack, a portion of the second dielectric layer formed on a portion of the conductive pedestal.

In one embodiment, forming the MTJ stack includes forming a patterned conductive hardmask on a stack of MTJ layers, and etching the stack of MTJ layers using an etch process that terminates on the conductive pedestal.

In one embodiment, forming the MTJ stack includes forming a fixed magnetic layer above the conductive pedestal, forming a tunneling layer on the fixed magnetic layer, and forming a free magnetic layer on the tunneling layer.

In one embodiment, forming the MTJ stack further includes forming a synthetic antiferromagnet (SAF) layer on the conductive pedestal, and forming the fixed magnetic layer on the SAF layer.

In one embodiment, the method further includes forming a second MTJ stack on the conductive pedestal.

What is claimed is:

1. A magnetic tunnel junction (MTJ) device, comprising:
a metal line disposed in a dielectric layer disposed above a substrate, the metal line recessed below an uppermost surface of the dielectric layer;
a conductive pedestal disposed on the metal line and laterally adjacent to the dielectric layer;
a magnetic tunnel junction (MTJ) stack disposed on the conductive pedestal.

2. The MTJ device of claim 1, wherein an uppermost surface of the conductive pedestal is co-planar with the uppermost surface of the dielectric layer.

3. The MTJ device of claim 1, wherein a portion of the conductive pedestal is not covered by the MTJ stack.

4. The MTJ device of claim 1, further comprising:
a second dielectric layer disposed on the dielectric layer and laterally adjacent to the MTJ stack, a portion of the second dielectric layer disposed on a portion of the conductive pedestal.

5. The MTJ device of claim 1, further comprising:
an upper electrode disposed on the MTJ stack, the upper electrode having, from a top-down perspective, substantially the same shape as the MTJ stack.

6. The MTJ device of claim 1, wherein the MTJ stack comprises a fixed magnetic layer disposed above the conductive pedestal, a tunneling layer disposed on the fixed magnetic layer, and a free magnetic layer disposed on the tunneling layer.

7. The MTJ device of claim 6, the MTJ stack further comprising:
a synthetic antiferromagnet (SAF) layer disposed directly between the fixed magnetic layer and the conductive pedestal.

8. The MTJ device of claim 1, further comprising:
a second MTJ stack disposed on the conductive pedestal.

9. A method of fabricating a magnetic tunnel junction (MTJ) device, the method comprising:
forming a metal line in a dielectric layer formed above a substrate;
recessing the metal line below an uppermost surface of the dielectric layer;
forming a conductive layer on the recessed metal line and over the uppermost surface of the dielectric layer;
planarizing the conductive layer to form a conductive pedestal on the metal line, the conductive pedestal confined within and laterally adjacent to the dielectric layer; and
forming a magnetic tunnel junction (MTJ) stack on the conductive pedestal.

10. The method of claim 9, wherein planarizing the conductive layer comprises forming an uppermost surface of the conductive pedestal co-planar with the uppermost surface of the dielectric layer.

11. The method of claim 9, wherein forming the MTJ stack comprises forming the MTJ stack on only a portion of the conductive pedestal.

12. The method of claim 9, further comprising:
forming a second dielectric layer on the dielectric layer and laterally adjacent to the MTJ stack, a portion of the second dielectric layer formed on a portion of the conductive pedestal.

13. The method of claim 9, wherein forming the MTJ stack comprises forming a patterned conductive hardmask on a stack of MTJ layers, and etching the stack of MTJ layers using an etch process that terminates on the conductive pedestal.

14. The method of claim 9, wherein forming the MTJ stack comprises forming a fixed magnetic layer above the conductive pedestal, forming a tunneling layer on the fixed magnetic layer, and forming a free magnetic layer on the tunneling layer.

15. The method of claim 14, wherein forming the MTJ stack further comprises forming a synthetic antiferromagnet (SAF) layer on the conductive pedestal, and forming the fixed magnetic layer on the SAF layer.

16. The method of claim 9, further comprising:
forming a second MTJ stack on the conductive pedestal.

17. A method of fabricating a magnetic tunnel junction (MTJ) device, the method comprising:
forming a metal line in a dielectric layer formed above a substrate;
recessing the metal line below an uppermost surface of the dielectric layer;
selectively forming a conductive layer on the recessed metal line to a height above the uppermost surface of the dielectric layer;
planarizing the conductive layer to form a conductive pedestal on the metal line, the conductive pedestal confined within and laterally adjacent to the dielectric layer; and
forming a magnetic tunnel junction (MTJ) stack on the conductive pedestal.

18. The method of claim 17, wherein planarizing the conductive layer comprises forming an uppermost surface of the conductive pedestal co-planar with the uppermost surface of the dielectric layer.

19. The method of claim 17, wherein forming the MTJ stack comprises forming the MTJ stack on only a portion of the conductive pedestal.

20. The method of claim 17, further comprising:
forming a second dielectric layer on the dielectric layer and laterally adjacent to the MTJ stack, a portion of the second dielectric layer formed on a portion of the conductive pedestal.

21. The method of claim 17, wherein forming the MTJ stack comprises forming a patterned conductive hardmask on a stack of MTJ layers, and etching the stack of MTJ layers using an etch process that terminates on the conductive pedestal.

22. The method of claim 17, wherein forming the MTJ stack comprises forming a fixed magnetic layer above the conductive pedestal, forming a tunneling layer on the fixed magnetic layer, and forming a free magnetic layer on the tunneling layer.

23. The method of claim 22, wherein forming the MTJ stack further comprises forming a synthetic antiferromagnet (SAF) layer on the conductive pedestal, and forming the fixed magnetic layer on the SAF layer.

24. The method of claim 17, further comprising:
forming a second MTJ stack on the conductive pedestal.
